(19) United States
(12) Patent Application Publication
(10) Pub. No.: US 2026/0198027 A1
(43) Pub. Date: Jul. 9, 2026

(54) INNER SPACER WITH STRESS ENGINEERING

(71) Applicant: International Business Machines Corporation, Armonk, NY (US)

(72) Inventors: Sung Dae Suk, Watervliet, NY (US); Pushparaj Pathak, Ballston Spa, NY (US); Andrew Mark Greene, Slingerlands, NY (US); Jun Liu, Clifton Park, NY (US); Mohammad Hasanuzzaman, Mechanicville, NY (US); Susan Ng Emans, Albany, NY (US); Effendi Leobandung, Stormville, NY (US); Julien Frougier, Albany, NY (US); Shahab Siddiqui, Clifton Park, NY (US); Rishikesh Krishnan, Cohoes, NY (US)

(21) Appl. No.: 19/008,722

(22) Filed: Jan. 3, 2025

(51) Int. Cl. H10D 30/01; H10D 30/00

(52) U.S. Cl. CPC H10D 30/0195; H10D 30/0191; H10D 30/502; H10D 30/507

(57) ABSTRACT

Embodiments of the disclosure include a semiconductor structure having channel regions stacked over a substrate and connected to source/drain regions. The semiconductor structure includes a buffer layer intervening between the channel regions and the source/drain regions and inner spacers formed in part of the buffer layer.

### BACKGROUND

The present invention generally relates to fabrication methods and resulting structures for integrated circuits (ICs), and more specifically, to fabrication methods and resulting structures configured and arranged for inner spacers with stress engineering by source/drain epitaxial material for nanosheets.

ICs (also referred to as a chip or a microchip) include electronic circuits on a wafer. The wafer is a semiconductor material, such as, for example, silicon or other materials. An IC is formed of a large number of devices, such as transistors, capacitors, resistors, etc., which are formed in layers of the IC and interconnected with wiring in the back-end-of-line (BEOL) layers of the wafer. on the wafer. Typical ICs are formed by first fabricating individual semiconductor devices using processes referred to generally as the front-end-of-line (FEOL). A metal-oxide-semiconductor field-effect transistor (MOSFET) is a transistor used for amplifying or switching electronic signals. The MOSFET has a source, a drain, and a metal oxide gate electrode. A conventional FET is a planar device where the entire channel region of the device is formed parallel and slightly below the planar upper surface of the semiconducting substrate. In contrast to a planar FET, there are so-called three-dimensional (3D) devices, such as a FinFET device, which is a three-dimensional structure. One type of device that shows promise for advanced integrated circuit products is generally known as a nanosheet transistor. In general, a nanosheet transistor has a fin-type channel structure that includes a plurality of vertically spaced-apart sheets of semiconductor material. A gate structure for the device is positioned around each of these spaced-apart layers of channel semiconductor material.

### SUMMARY

Embodiments of the present invention are directed to providing inner spacers with stress engineering by source/drain epitaxial material for nanosheets. A semiconductor structure includes channel regions stacked over a substrate and connected to source/drain regions and a buffer layer intervening between the channel regions and the source/drain regions. The semiconductor structure includes inner spacers formed in part of the buffer layer.

According to one or more embodiments, a method includes providing channel regions stacked over a substrate and forming a buffer layer on the channel regions, the buffer layer intervening between the channel regions and source/drain regions. Inner spacers are formed in part of the buffer layer.

According to one or more embodiments, a semiconductor structure includes channel regions vertically stacked over a substrate and connected to source/drain regions. The semiconductor structure includes a buffer layer intervening between the channel regions and the source/drain regions, the buffer layer comprising bump portions that extend laterally. The semiconductor structure includes inner spacers formed in the bump portions of the buffer layer.

According to one or more embodiments, a method includes providing a stack of alternating layers of channel regions and sacrificial layers and etching the channel regions resulting in a partial etch of the sacrificial layers so as to form extended portions of the sacrificial layers. The method includes forming a buffer layer on the channel regions and the sacrificial layers such that bump portions of the buffer layer are conformally formed on the extended portions of the sacrificial layers. The method includes replacing the sacrificial layers with inner spacer material. Also, the method includes etching the inner spacer material to leave inner spacers remaining in the bump portions of the buffer layer and forming source/drain regions on the buffer layer.

Other embodiments of the present invention implement features of the above-described devices/structures in methods and/or implement features of the methods in devices/structures.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIGS. 1A, 1B, 1C, 1D, and 1E respectively depict a top view and cross-sectional views of a portion of an integrated circuit (IC) under-fabrication after fabrication operations according to one or more embodiments;

FIGS. 2A, 2B, 2C, 2D, and 2E depict a top view and cross-sectional views of a portion of an IC under-fabrication after fabrication operations according to one or more embodiments;

FIGS. 3A, 3B, 3C, 3D, and 3E depict a top view and cross-sectional views of a portion of an IC under-fabrication after fabrication operations according to one or more embodiments;

FIGS. 4A, 4B, 4C, 4D, and 4E depict a top view and cross-sectional views of a portion of an IC under-fabrication after fabrication operations according to one or more embodiments;

FIGS. 5A, 5B, 5C, 5D, and 5E depict a top view and cross-sectional views of a portion of an IC under-fabrication after fabrication operations according to one or more embodiments;

FIGS. 6A, 6B, 6C, 6D, and 6E depict a top view and cross-sectional views of a portion of an IC under-fabrication after fabrication operations according to one or more embodiments;

FIGS. 7A, 7B, 7C, 7D, and 7E depict a top view and cross-sectional views of a portion of an IC under-fabrication after fabrication operations according to one or more embodiments;

FIGS. 8A, 8B, 8C, 8D, and 8E depict a top view and cross-sectional views of a portion of an IC under-fabrication after fabrication operations according to one or more embodiments;

FIGS. 9A, 9B, 9C, 9D, and 9E depict a top view and cross-sectional views of a portion of an IC under-fabrication after fabrication operations according to one or more embodiments;

FIGS. 10A, 10B, 10C, 10D, and 10E depict a top view and cross-sectional views of a portion of an IC under-fabrication after fabrication operations according to one or more embodiments;

FIGS. 11A, 11B, 11C, 11D, and 11E depict a top view and cross-sectional views of a portion of an IC under-fabrication after fabrication operations according to one or more embodiments;

FIGS. 12A, 12B, 12C, 12D, and 12E depict a top view and cross-sectional views of a portion of an IC under-fabrication after fabrication operations according to one or more embodiments;

FIGS. 13A, 13B, 13C, 13D, and 13E depict a top view and cross-sectional views of a portion of an IC under-fabrication after fabrication operations according to one or more embodiments;

FIGS. 14A, 14B, 14C, 14D, and 14E depict a top view and cross-sectional views of a portion of an IC under-fabrication after fabrication operations according to one or more embodiments;

FIGS. 15A, 15B, 15C, 15D, and 15E depict a top view and cross-sectional views of a portion of an IC under-fabrication after fabrication operations according to one or more embodiments;

FIG. 16 depicts a flowchart of a method of forming a semiconductor structure according to one or more embodiments; and

FIG. 17 depicts a flowchart of a method of forming a semiconductor structure according to one or more embodiments.

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The MOSFET is a transistor used for amplifying or switching electronic signals. The MOSFET has a source, a drain, and a metal gate electrode. The metal gate is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (NFET) and p-type field effect transistors (PFET) are two types of complementary MOSFETs. The NFET includes n-doped source and drain junctions and uses electrons as the current carriers. The PFET includes p-doped source and drain junctions and uses holes as the current carriers.

The nanowire or nanosheet MOSFET is a type of MOSFET that uses multiple stacked nanowires/nanosheets to form multiple channel regions. The gate regions of a nanosheet MOSFET are formed by wrapping gate stack materials around the multiple nanowire/nanosheet channels. This configuration is known as a gate-all-around (GAA) FET structure. The nanowire/nanosheet MOSFET device mitigates the effects of short channels and reduces drain-induced barrier lowering.

The GAA nanosheet FET structures can provide superior electrostatics. In contrast to known Fin-type FET (FinFET) structures in which the fin element of the transistor extends “up” out of the transistor, nanosheet FET designs implement the fin as a silicon nanosheet/nanowire. In a known configuration of a GAA nanosheet FET, a relatively small FET footprint is provided by forming the channel region as a series of nanosheets (i.e., silicon nanowires). A known GAA configuration includes a source region, a drain region, and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial nanosheets. The sacrificial nanosheets are released from the channel nanosheets before the FET device is finalized.

One or more embodiments provide a new inner spacer process with stress engineering by source/drain epitaxial material for nanosheets. The semiconductor structure includes inner spacers that are thinner than nanosheet to nanosheet spacing, which are formed later in the fabrication process. The inner spacers may include oxide or other insulator materials. A uniform continuous epitaxial buffer layer/structure is formed without defects between the source/drain regions and the channel regions. The inner spacers formed in portions of the buffer layer.

As technical effects and solutions, one or more embodiments provide inner spacers later in the fabrication process without the typical earlier inner spacer steps. As will be shown later, this improves current drive and reduces parasitic capacitance. The uniform crystalline structure of the buffer layer serves as the underlying layer (or seed layer) for epitaxially growing the source/drain regions with good crystallinity for stress engineering.

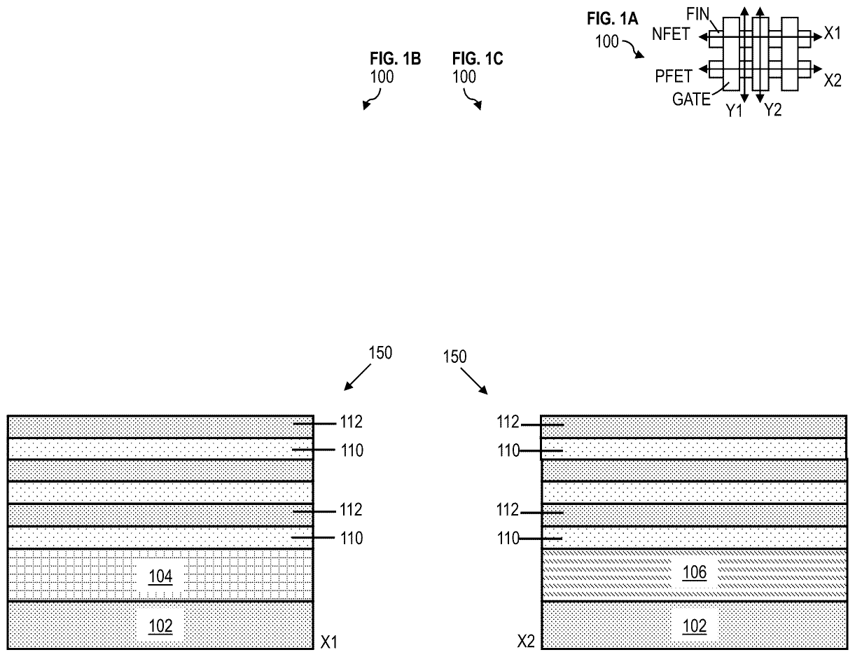

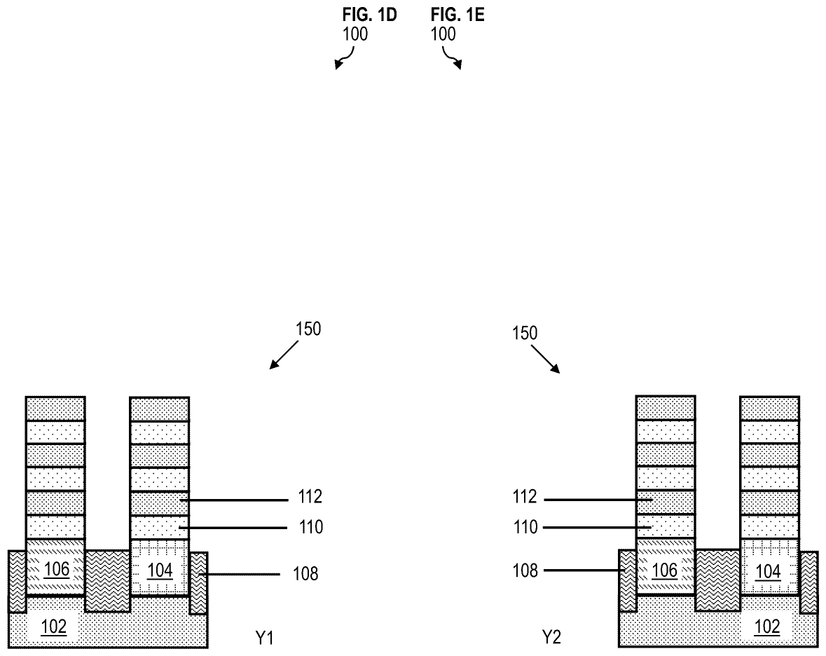

Turning now to a more detailed description of aspects of the present invention, FIG. 1A depicts a top view of a simplified illustration of a portion of an integrated circuit (IC) 100. FIG. 1B depicts a cross-sectional view taken along X1 of the IC 100, and FIG. 1C depicts a cross-sectional view taken along X2 of the IC 100. FIG. 1D depicts a cross-sectional view taken along Y1 of the IC 100, and FIG. 1E depicts a cross-sectional view taken along Y2 of the IC 100. For ease of understanding, some layers may be omitted from the top view so as not to obscure the figure and to view layers underneath. At times, the top view may represent future locations of on the IC. As such, the top view is intended to provide a simplified illustration and a general orientation, but the top view is not intended to be a complete representation of the device. Standard semiconductor fabrication techniques can be utilized to fabricate the IC 100 as understood by one of ordinary skill in the art. Any suitable lithography processes including deposition techniques and etching techniques can be utilized herein.

It should be appreciated that the X1 cross-sectional view depicts the NFET cross-gate view while the X2 cross-sectional view depicts the PFET cross-gate view. The Y1 cross-sectional view depicts the source/drain regions, and the Y2 cross-sectional view depicts the gate region.

FIGS. 1A, 1B, 1C, 1D, and 1E depict the IC 100 having a wafer where several fabrication processes have been performed. The figures illustrate the IC 100 after nanosheet stack growth with alternating nanosheets. A nanosheet stack 150 is formed on a substrate 102 (or wafer). The substrate 102 may be formed of (pure) silicon. Other suitable semiconductor materials can be utilized for the substrate 102. The nanosheet stack 150 is formed with alternating layers of semiconductor layers 112 and sacrificial layers 110. The semiconductor layers 112 may include substantially pure silicon. The semiconductor layers 112 are the channel regions for the nanosheet FET device. The semiconductor layers 112 are nanosheets, and the nanosheets can have a thickness of, for example, 5 nanometers. The thickness of a nanosheet can range from about 2-10 nm, and other ranges are possible. The sacrificial layers 110 are formed of silicon germanium (SiGe), where germanium has an atomic percent (%) of about 25% and silicon is the remainder. In one or more embodiments, the atomic percent of germanium can range from about 15-30% while silicon is the remainder in the sacrificial layers 110.

In FIG. 1B, the cross-sectional view along X1 is representative of an NFET device. Accordingly, FIG. 1B may include a p-type doped layer 104 intervening between the substrate 102 and the bottom most layer of the nanosheet stack 150. The p-type doped layer 104 can include a semiconductor material doped with p-type dopants. In one or more embodiments, the p-type doped layer 104 may be replaced with an isolation dielectric layer

In FIG. 1C, the cross-sectional view along X2 is representative of a PFET device. Accordingly, FIG. 1C may include an n-type doped layer 106 intervening between the substrate 102 and the bottom most layer of the nanosheet stack 150. The n-type doped layer 106 can include a semiconductor material doped with n-type dopants. In one or more embodiments, the n-type doped layer 106 may be replaced with an isolation dielectric layer.

Etching is performed to pattern fins in the nanosheet stack 150, and shallow trench isolation (STI) regions 108 are formed in the substrate 102. Example materials of the STI regions 108 can include oxides, low-k dielectric materials, ultra-low-k dielectric materials, etc.

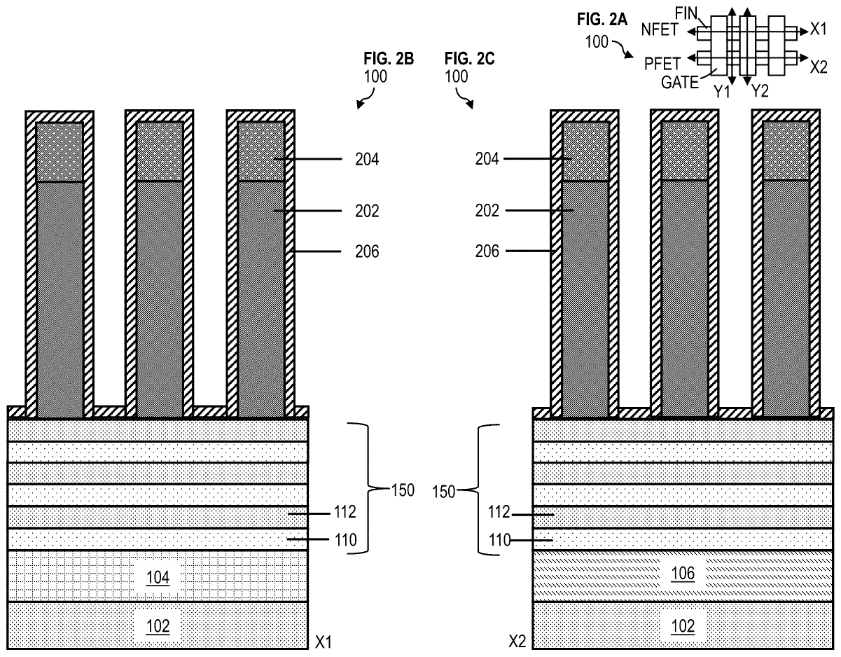

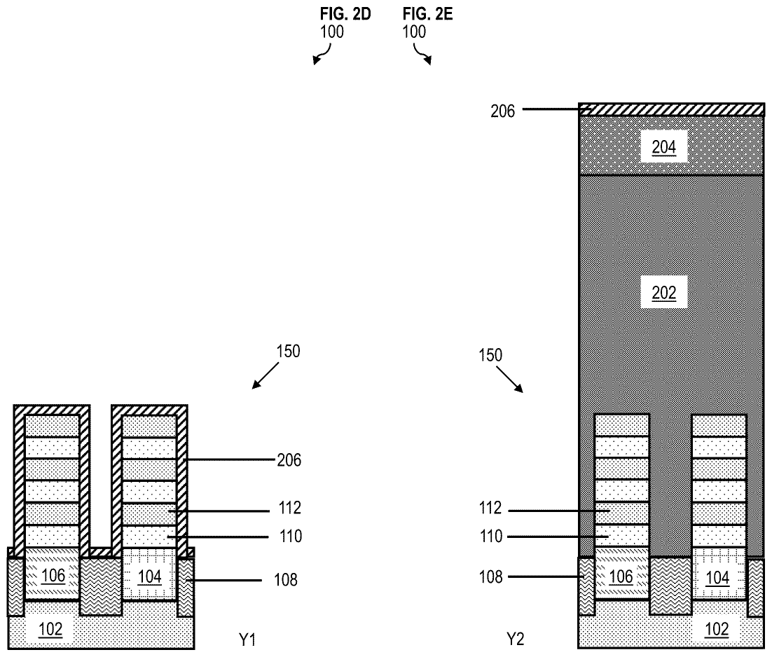

FIGS. 2A, 2B, 2C, 2D, and 2E depict the IC 100 after dummy gate formation and conformal spacer deposition. Sacrificial gate material is formed on the IC 100 eventually resulting in dummy gates 202, and a hard mask layer 204 is formed on top of the sacrificial gate material. The hard mask layer 204 is patterned such that hard mask layer 204 is etched from the nanosheet stack 150 in FIG. 2D. Photoresist materials may be utilized to pattern the hard mask layer 204. The (patterned) hard mask layer 204 is utilized to etch the sacrificial gate material into the dummy gates 202. A wet etch or dry etch may be utilized. The etching stops on and exposes a top layer of the nanosheet in FIGS. 2B, 2C, and 2E. In FIG. 2D, the nanosheet stack 150 and the STI regions 108 are exposed. Example materials of the dummy gates 202 can include amorphous silicon, polycrystalline silicon, etc. Example materials of the hard mask layer 204 can include nitride materials such as silicon nitride, silicon oxynitride, etc.

A spacer material 206 is conformally deposited. The spacer material 206 may be referred to as spacer zero (0). Example materials of the spacer material 206 may include SiOC, SiBCN, SiOCN, SiC, SiOCN, SiN, etc. The materials of the spacer material 206 are selected to have etch selectivity in subsequent fabrication operations.

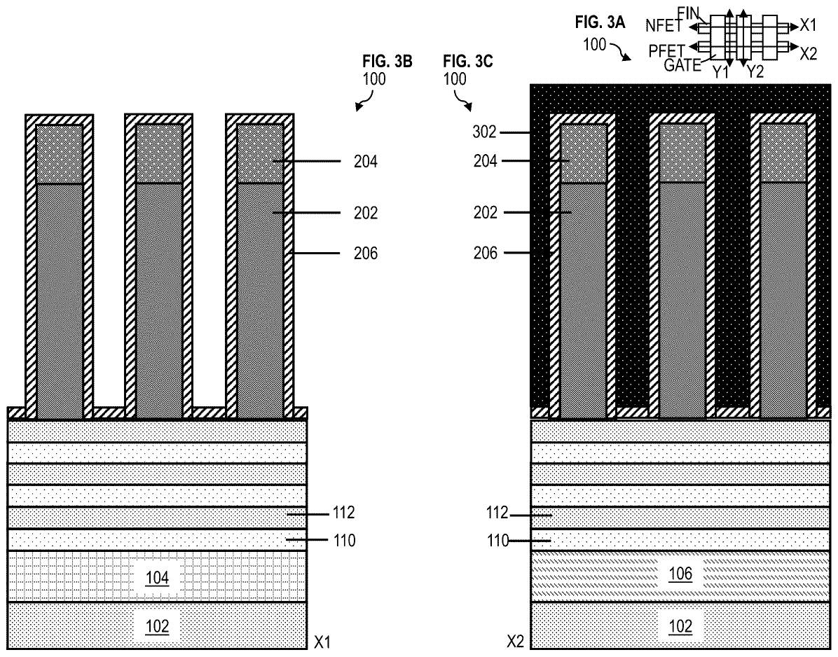

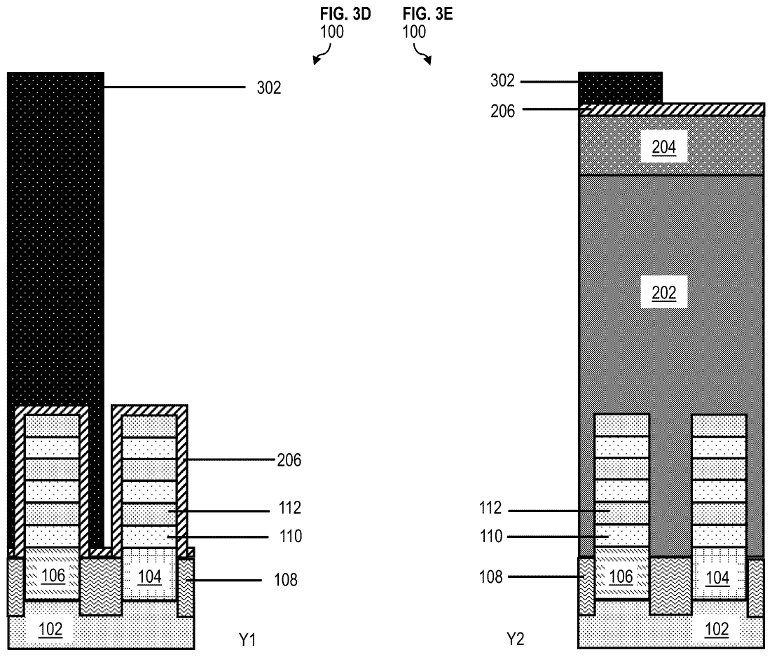

FIGS. 3A, 3B, 3C, 3D, and 3E depict the IC 100 after preparation for NFET patterning. A block mask 302 can be deposited and patterned to protect the PFET device while exposing the NFET device. The block mask 302 can include an organic planarization layer (OPL) and other suitable materials.

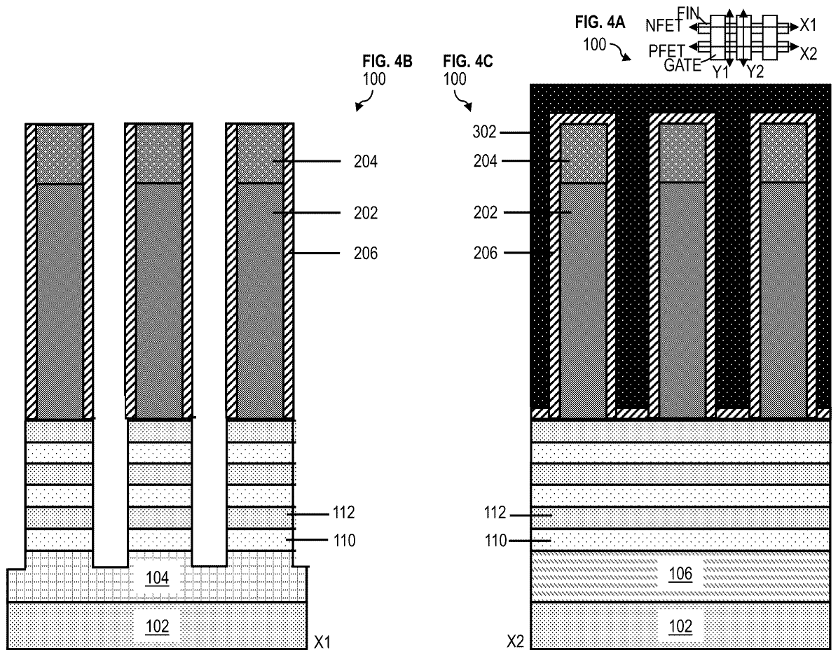

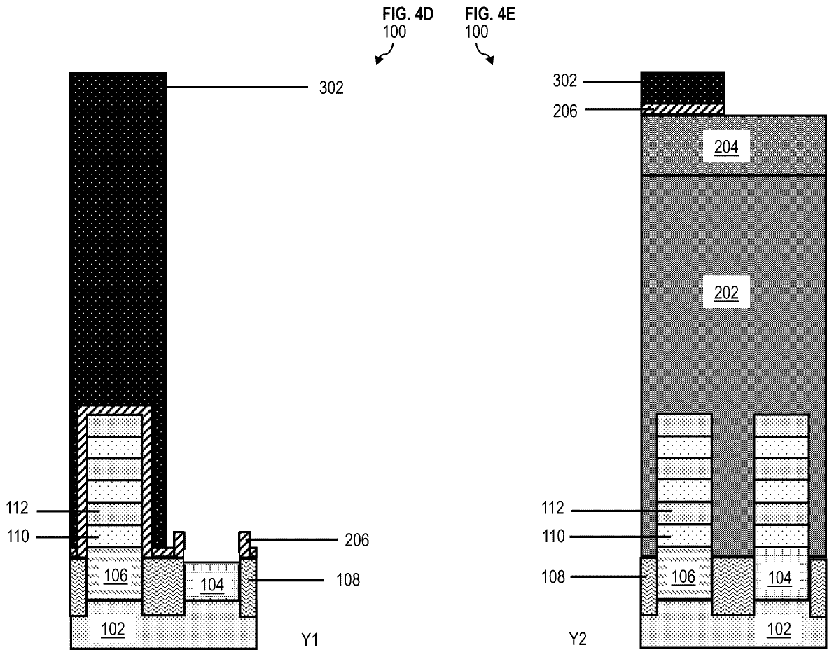

FIGS. 4A, 4B, 4C, 4D, and 4E depict the IC 100 after NFET recess. Etching is performed to recess exposed portions of the semiconductor layers 112, the sacrificial layers 110, and the p-type doped layer 104 of the NFET device, while the PFET device is protected by the block mask 302. Example etching may include reactive ion etching (RIE).

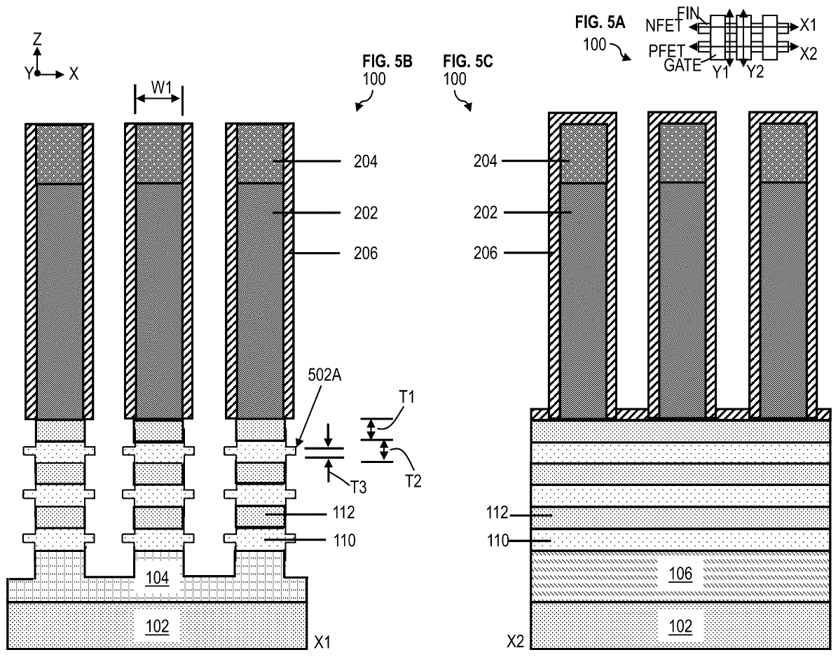

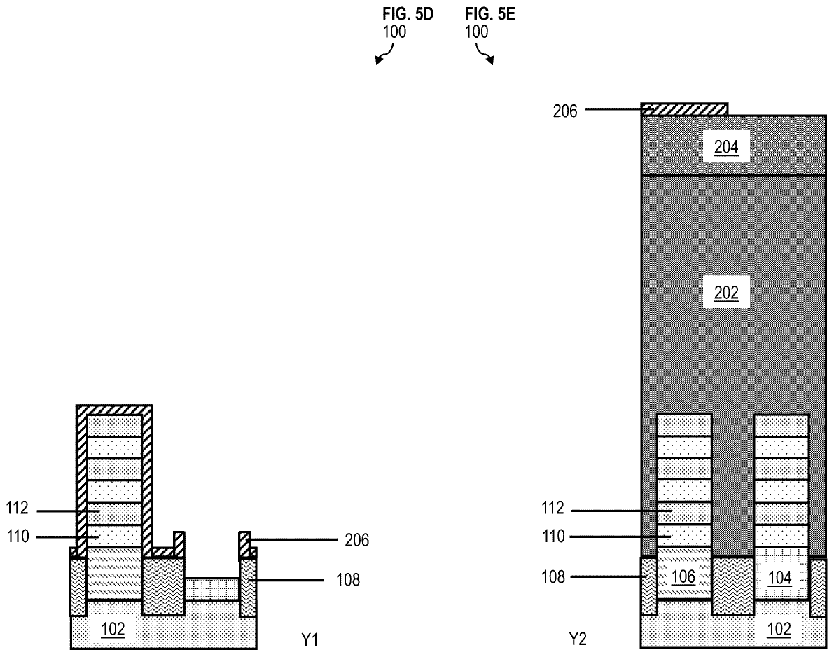

FIGS. 5A, 5B, 5C, 5D, and 5E depict the IC 100 after NFET silicon sheet recess. Etching is performed to laterally trim (e.g., in the x-axis) the semiconductor layers 112, which may be silicon. This etching also laterally etches part of the sacrificial layers 110, resulting in extensions 502A of sacrificial layers 110 in the x-axis. For example, the silicon sheet recess carves into the silicon germanium material of the sacrificial layers 110 because of limited selectivity. The etching trims the semiconductor layers 112 and trims parts of the sacrificial layers 110 to the width W1 of the hard mask layer 204 or the dummy gate 202 in the x-axis. The extensions 502A are on the sides of the sacrificial layers 110 and extend beyond the width W1. A portion of the sacrificial layers 110 can be trimmed to the width W1 while the extensions 502A have a width that extends beyond the width W1.

The semiconductor layers 112 may have a thickness T1, the sacrificial layers 110 may have a thickness T2, and the extensions 502A may have thickness T3 in the z-axis. The thickness T3 is less than the thickness T1 or thickness T2 in the z-axis.

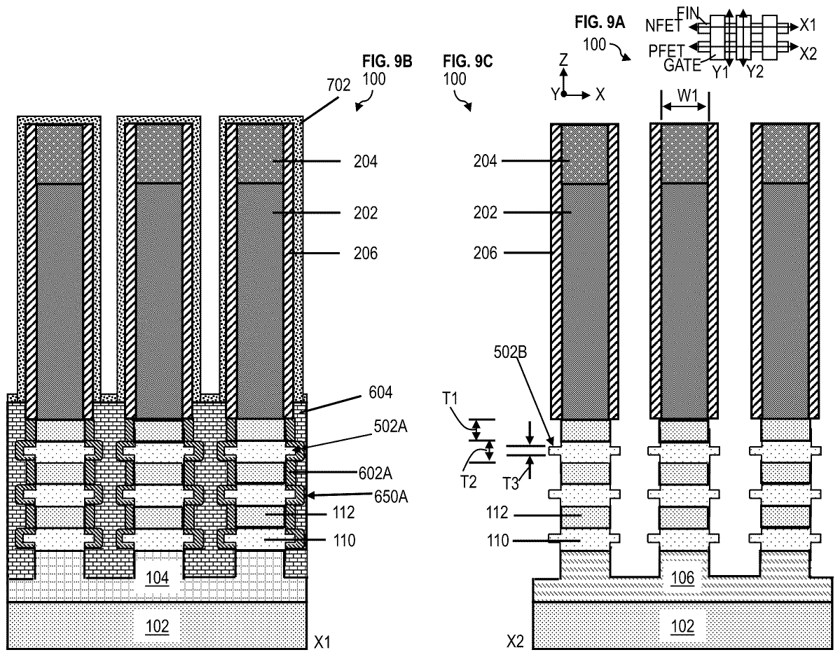

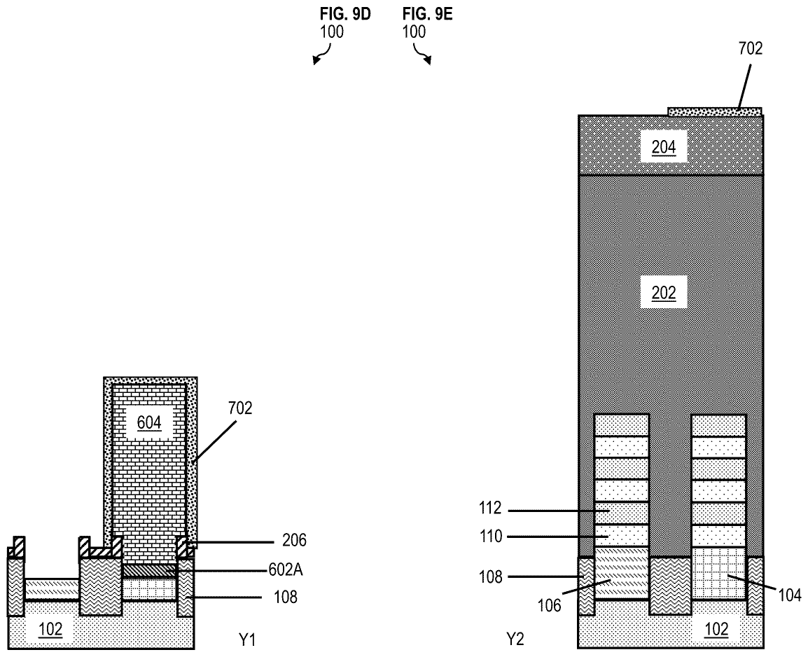

An analogous process for the PFET device results in extensions 502B of sacrificial layers 110, as depicted in FIG. 9C. A wet or dry etch may be utilized. An example etchant to achieve the extensions 502A and 502B of sacrificial layers 110 may include fluorine-based gases, chlorine-based gases, etc.

The block mask 302 is removed. The block mask 302 may be removed by ashing.

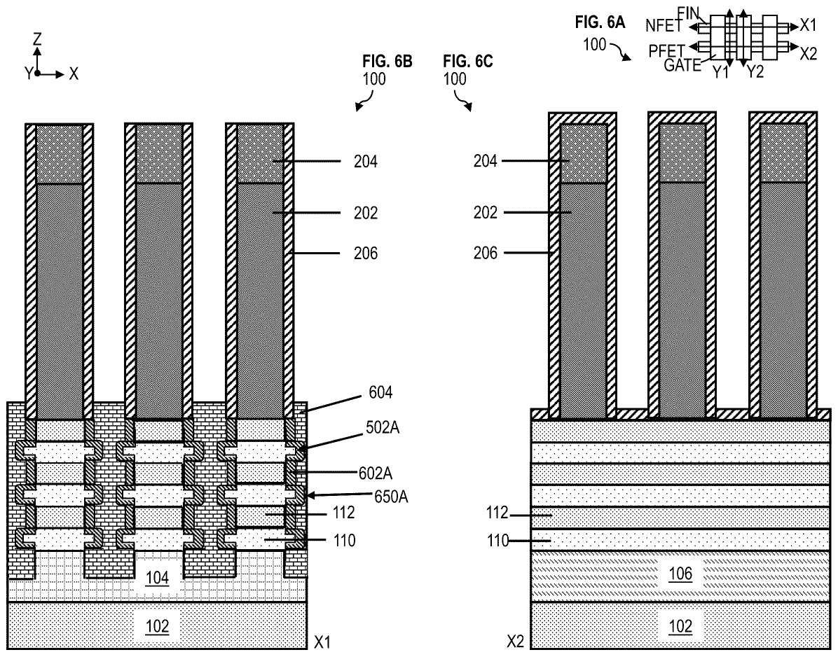

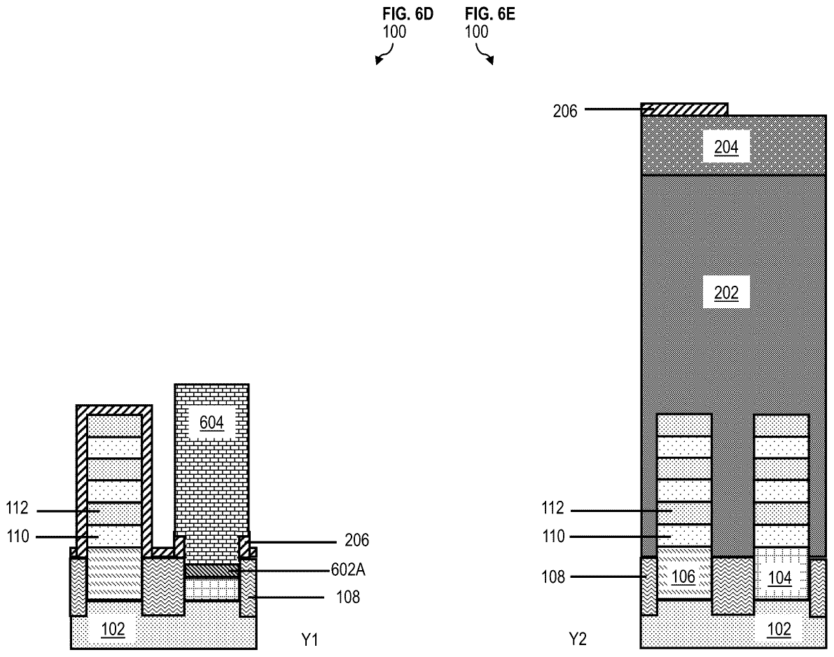

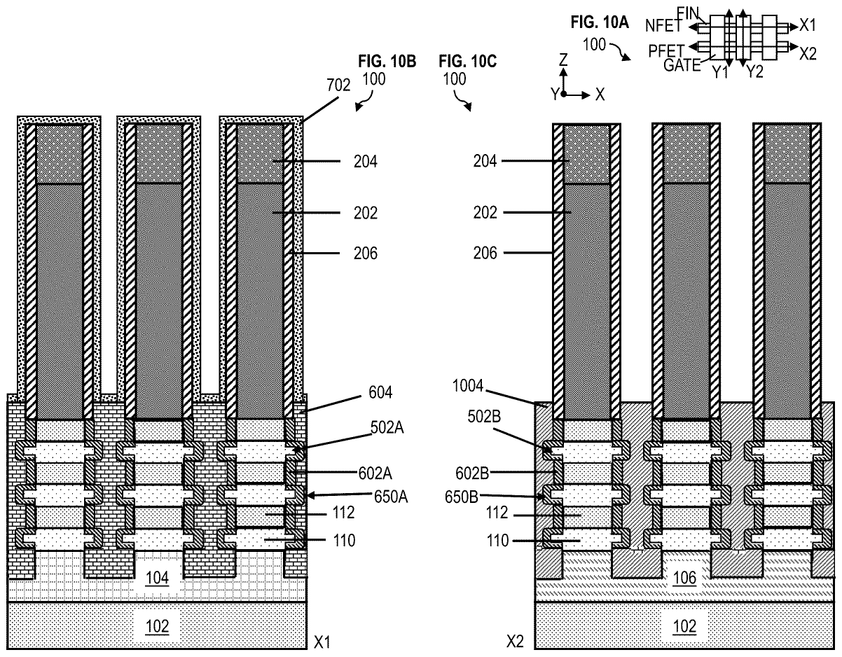

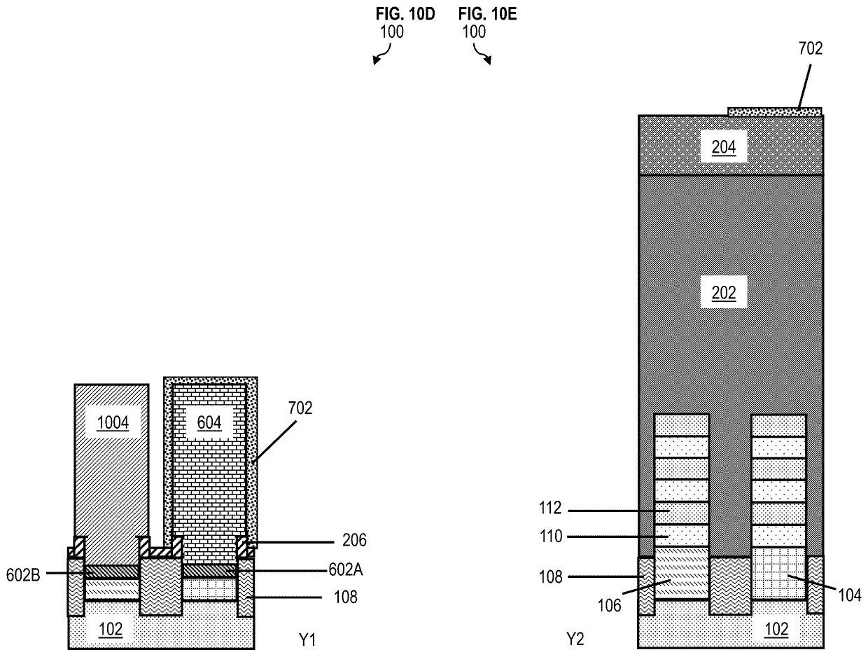

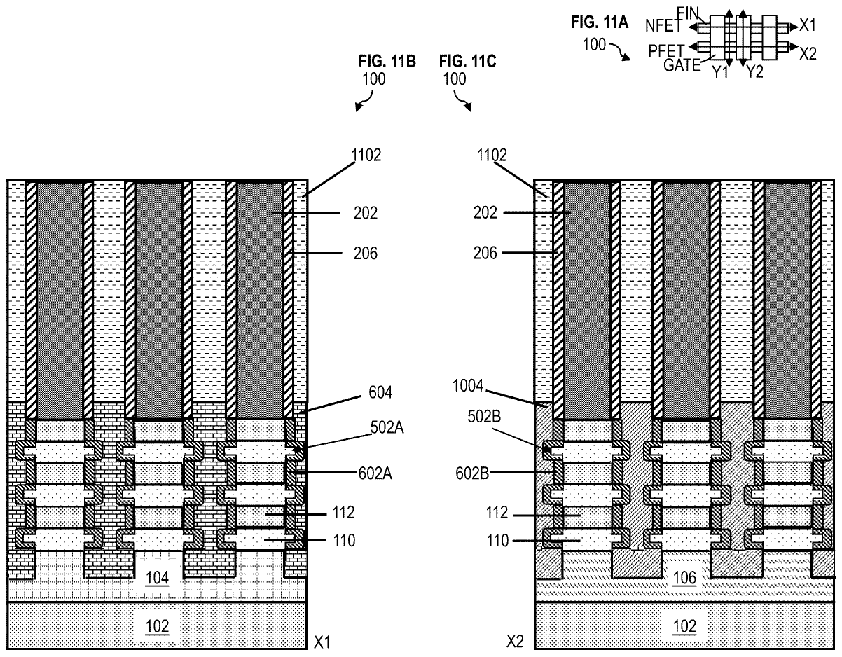

FIGS. 6A, 6B, 6C, 6D, and 6E depict the IC 100 after deposition of NFET epitaxial material. For the NFET device, a buffer layer 602A is deposited on the sides of the semiconductor layers 112 and sacrificial layers 110. The buffer layer 602A is conformally deposited onto the extensions 502A thereby forming (curved) bump portions 650A of the buffer layer 602A. The bump portions 650A extend laterally in the x-axis in accordance with the extensions 502A. By analogy, a buffer layer 602B is deposited on the sides of the semiconductor layers 112 and sacrificial layers 110 of the PFET device, and the buffer layer 602B is conformally deposited onto the extensions 502B thereby forming (curved) bump portions 650B of the buffer layer 602B, as depicted in FIG. 10C.

The buffer layers 602A and 602B may generally be referred to as buffer layers 602. In one or more embodiments, the buffer layers 602 may be formed of undoped silicon material, which is utilized to control (e.g., prevent) epitaxial dopant diffusion into the channel regions (e.g., semiconductor layers 112) during source/drain formation and is utilized to protect the source/drain regions during polysilicon pull (e.g., channel release).

Semiconductor material is epitaxially grown from the buffer layer 602A. The deposited semiconductor material can be doped with n-type or p-type dopants according to whether an n-type or p-type transistor is being formed, to result in source/drain regions. As best seen in FIGS. 6B and 6D, n-type epitaxial material is grown with the crystalline structure of the buffer layer 602A to form source/drain regions 604 for the NFET device. Because the buffer layer 602A is a continuous piece of material, the epitaxial material of the source/drain regions 604 is grown with an ideal crystallinity for stress engineering. Stress engineering for source/drain regions in semiconductor devices involves techniques to introduce or manage mechanical stress in the transistor channel to enhance carrier mobility and improve device performance.

Unlike the state-of-the-art, the source/drain regions are not grown from the channel regions in the x-axis and the substrate in the z-axis, which result in a crystalline grain extending laterally from the channel regions and another crystalline grain extending vertically from the substrate. Further, each nanosheet forming the channel region grows laterally with its own grain. These different types of grain patterns may not be ideal for stress engineering.

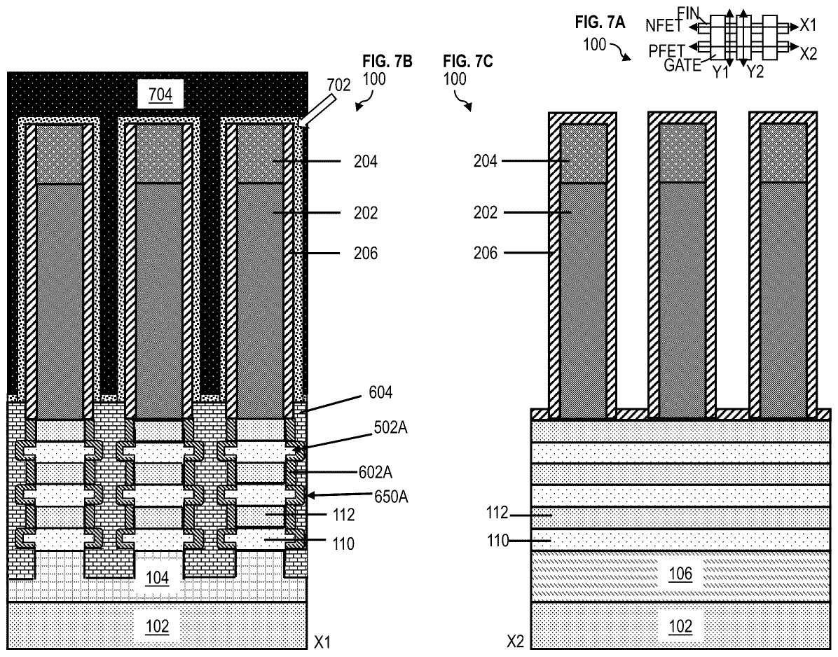

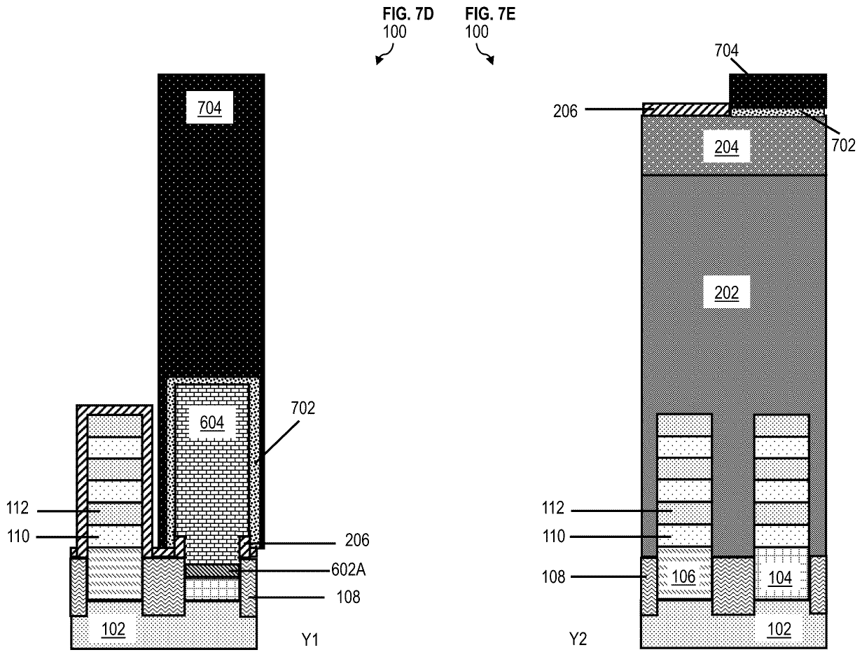

FIGS. 7A, 7B, 7C, 7D, and 7E depict the IC 100 after depositing a patterning liner and preparation for PFET patterning. A liner 702 is deposited, and a block mask 704 can be deposited and patterned to protect the NFET device while exposing the PFET device. The patterning of the block mask 704 removes the liner 702 from the PFET device. The block mask 704 can include an OPL layer. Example materials of the liner 702 may include SiN, SiO₂, SiC, etc.

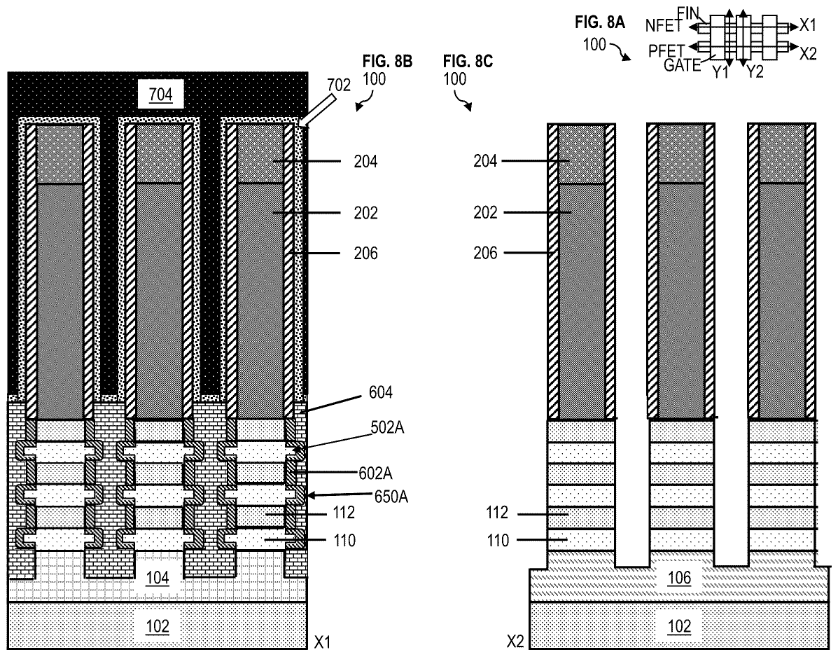

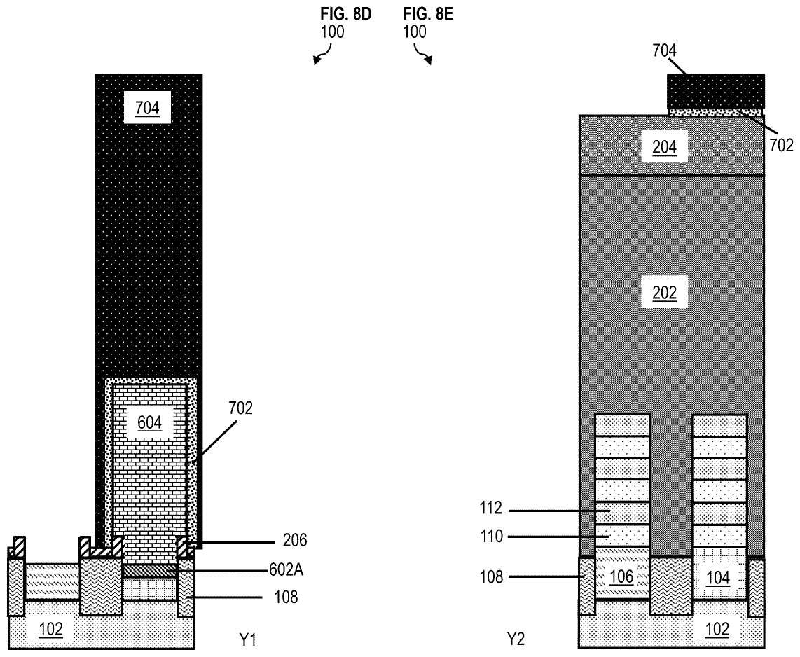

FIGS. 8A, 8B, 8C, 8D, and 8E depict the IC 100 after PFET recess. Etching is performed to recess exposed portions of the semiconductor layers 112, the sacrificial layers 110, and the n-type doped layer 106 of the PFET device, while the NFET device is protected by the block mask 704. Example etching may include reactive ion etching (RIE).

FIGS. 9A, 9B, 9C, 9D, and 9E depict the IC 100 after PFET silicon sheet recess. Etching is performed to laterally trim (e.g., in the x-axis) the semiconductor layers 112, which may be silicon. This etching also laterally etches part of the sacrificial layers 110, resulting in extensions 502B of sacrificial layers 110 in the x-axis. For example, the silicon sheet recess carves into the silicon germanium material of the sacrificial layers 110 because of limited selectivity. The etching trims the semiconductor layers 112 and trims parts of the sacrificial layers 110 to the width W1 of the hard mask layer 204 or the dummy gate 202 in the x-axis. A wet or dry etch may be utilized. The extensions 502A are on the sides of the sacrificial layers 110 and extend beyond the width W1.

As noted herein, the semiconductor layers 112 may have a thickness T1, the sacrificial layers 110 may have a thickness T2, and the extensions 502B may have thickness T3 in the z-axis. The thickness T3 is less than the thickness T1 or thickness T2.

The block mask 704 is removed. The block mask 704 may be removed by ashing. The liner 702 remains on the NFET device in preparation to form the PFET source/drain regions.

FIGS. 10A, 10B, 10C, 10D, and 10E depict the IC 100 after deposition of PFET epitaxial material. For the PFET device, a buffer layer 602B is deposited on the sides of the semiconductor layers 112 and sacrificial layers 110. As noted herein, the buffer layer 602B is conformally deposited onto the extensions 502B thereby forming (curved) bump portions 650B of the buffer layer 602B. The bump portions 650B extend laterally in the x-axis in accordance with the extensions 502B.

While protecting the NFET device with the liner 702, semiconductor material is epitaxially grown from the buffer layer 602B. The deposited semiconductor material can be doped with n-type or p-type dopants according to whether an n-type or p-type transistor is being formed, to result in source/drain regions. As best seen in FIGS. 10C and 10D, p-type epitaxial material is grown with the crystalline structure of the buffer layer 602B to form source/drain regions 1004 for the PFET device. Because the buffer layer 602B is a continuous piece of material, the epitaxial material of the source/drain regions 1004 is grown with an ideal crystallinity for stress engineering. Stress engineering for source/drain regions in semiconductor devices involves techniques to introduce or manage mechanical stress in the transistor channel to enhance carrier mobility and improve device performance.

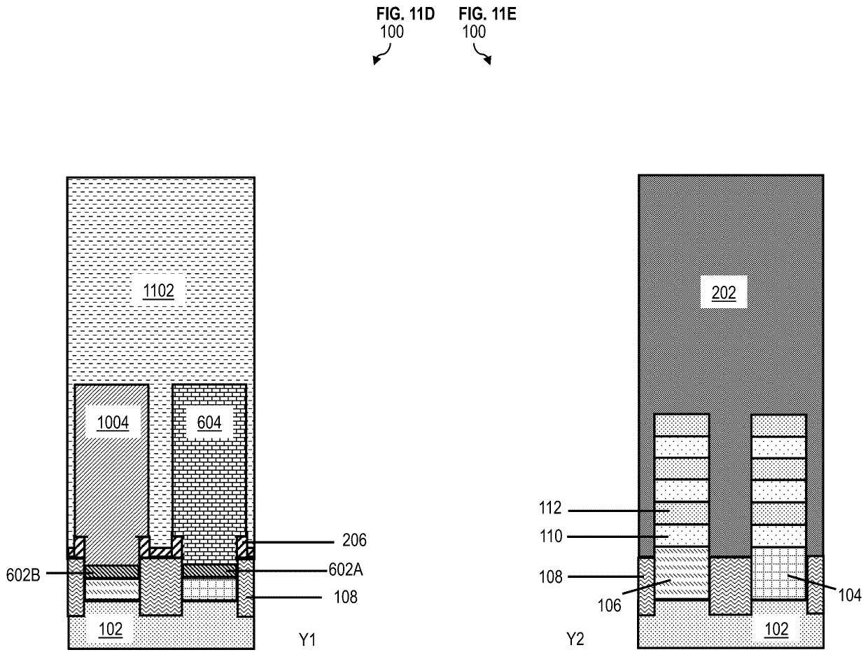

FIGS. 11A, 11B, 11C, 11D, and 11E depict the IC 100 after removing the liner, depositing an interlayer dielectric, and etching the hard mask layer. Etching can be performed to selectively remove the liner 702. Deposition is performed to form an interlayer dielectric (ILD) layer 1102. A RIE etch may be performed to remove the hard mask layer 204 so as to expose the dummy gate 202 in preparation for the replacement metal gate process. In one or more embodiments, the RIE etch can etch back portions of the ILD layer 1102.

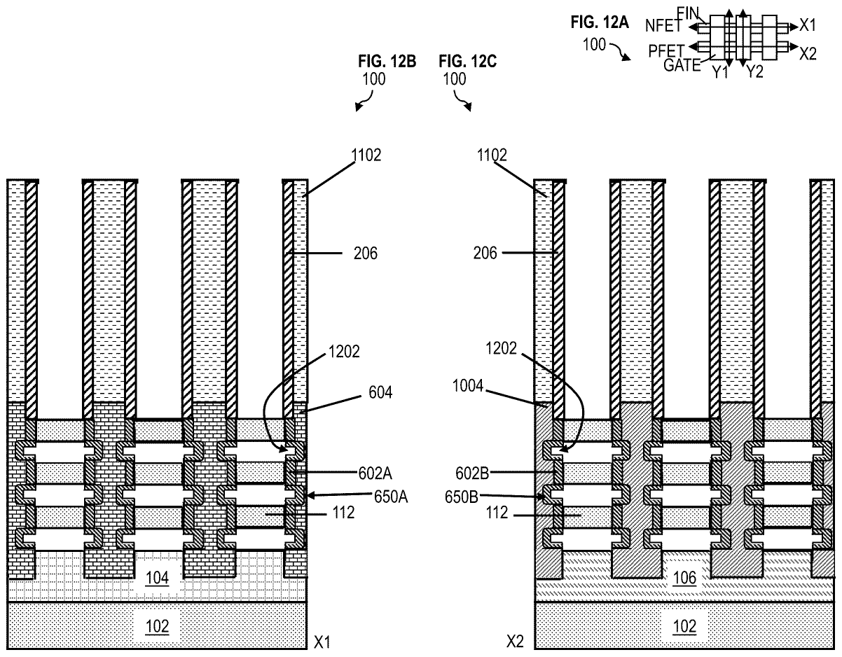

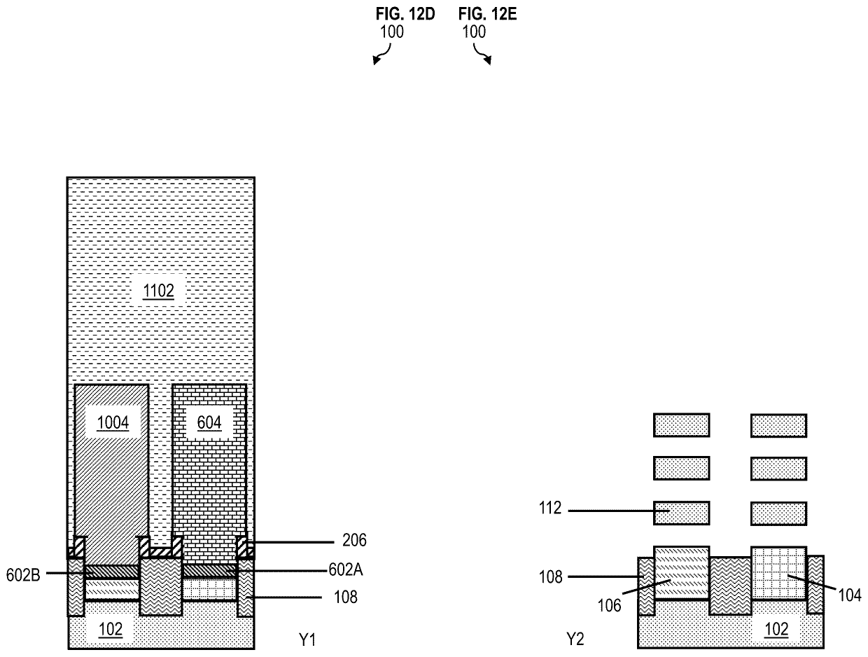

FIGS. 12A, 12B, 12C, 12D, and 12E depict the IC 100 after polysilicon pull and channel release. Etching is selectively performed to remove the dummy gate 202, and further etching is performed to remove the sacrificial layers 110 thereby releasing the semiconductor layer 112. The semiconductor layers 112 serve as the channel regions for the transistors. The etching leaves gaps 1202 in the (curved) bump portions 650A and 650B of the buffer layers 602A and 602B, respectively.

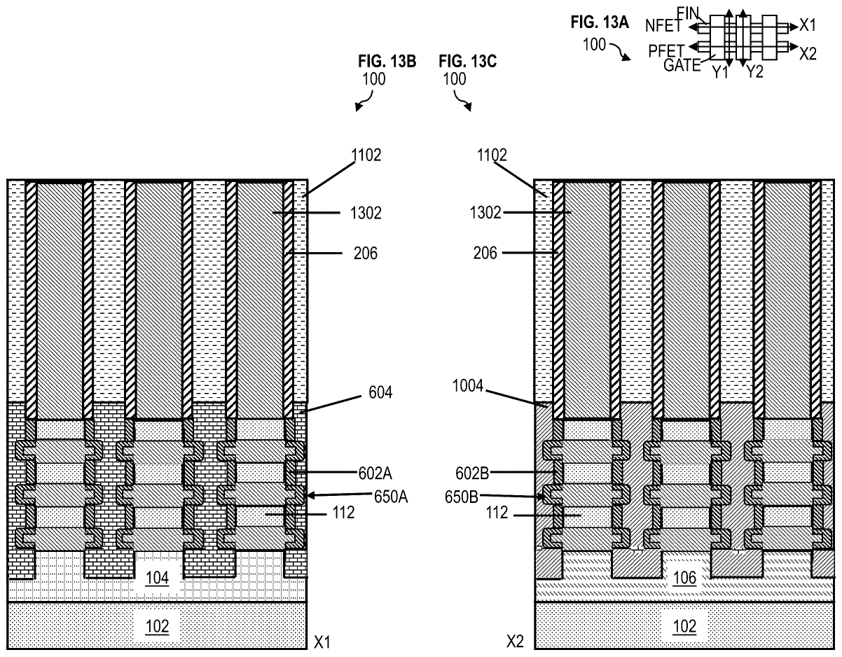

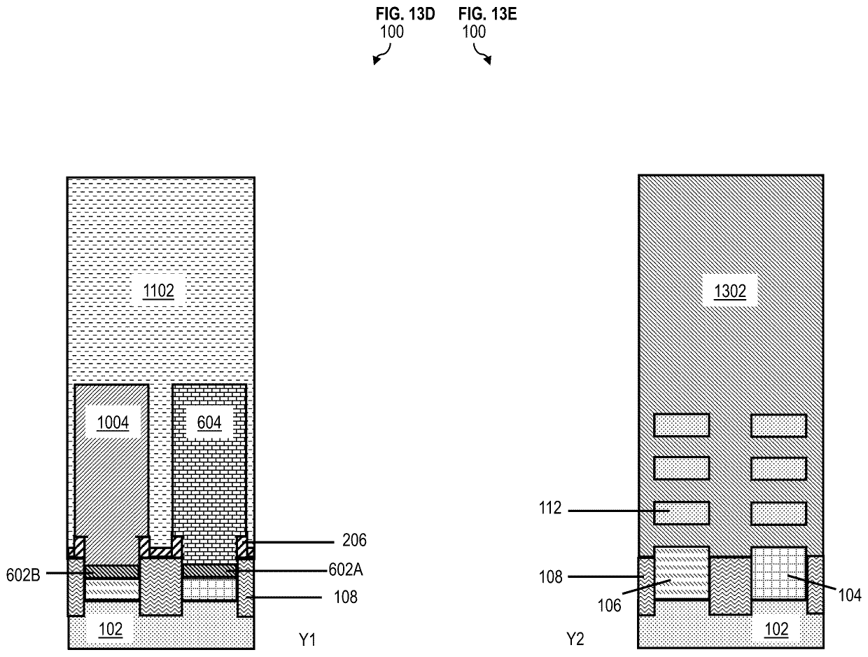

FIGS. 13A, 13B, 13C, 13D, and 13E depict the IC 100 after dielectric deposition in preparation for late inner spacer formation. Dielectric material 1302 is conformally deposited in preparation to form inner spacers. The dielectric material 1302 is formed in the gaps 1202 in the bump portions 650A and 650B of the buffer layers 602A and 602B, respectively. The dielectric material 1302 may be an oxide material such as, for example, silicon dioxide, low-k dielectric, etc. Examples of the dielectric material 1302 may include low-k dielectric materials, ultra-low-k dielectric materials, etc. The dielectric material 1302 is selected to be selectively etched without etching the other materials during a subsequent an etch back operation.

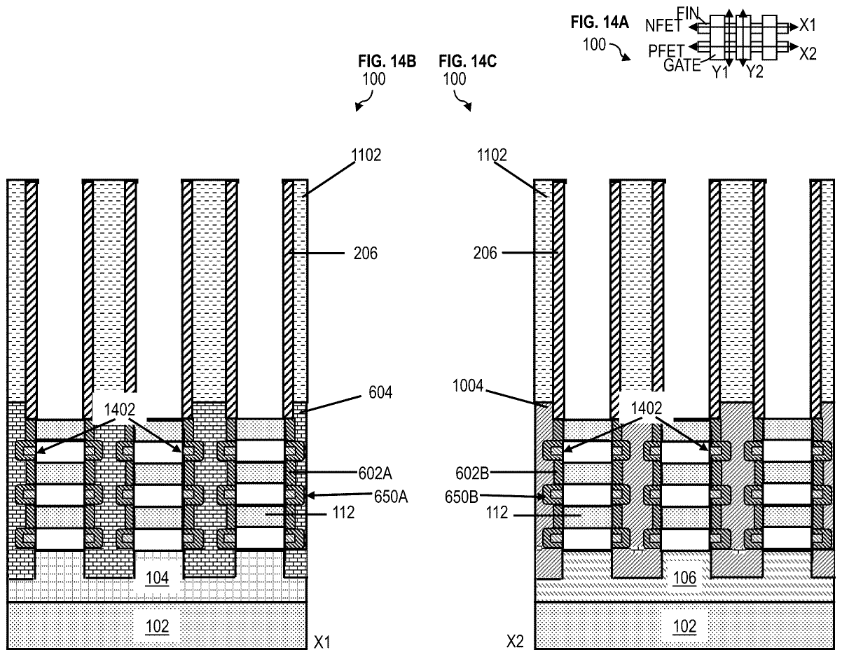

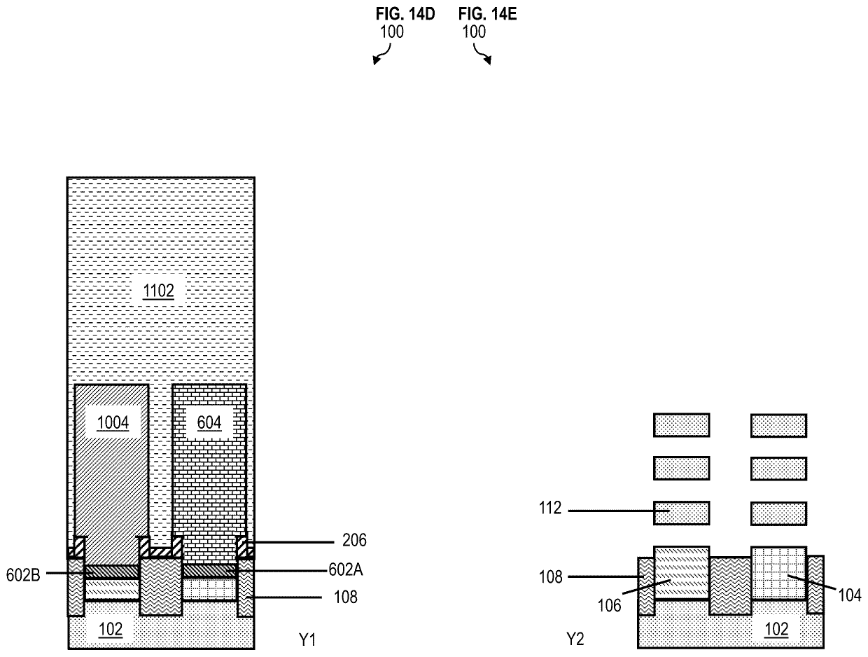

FIGS. 14A, 14B, 14C, 14D, and 14E depict the IC 100 after late inner spacer formation. Etching is performed to etch back the dielectric material 1302. The etch back removes the dielectric material 1302 but leaves portions of the dielectric material 1302 in the gaps 1202 in the (curved) bump portions 650A and 650B of the buffer layers 602A and 602B. The remaining portions of dielectric material 1302 in the gaps 1202 are inner spacers 1402. These are late inner spacers because inner spacers are typically formed in much earlier fabrication operations by etching outer portions of the sacrificial layers in the state-of-the-art.

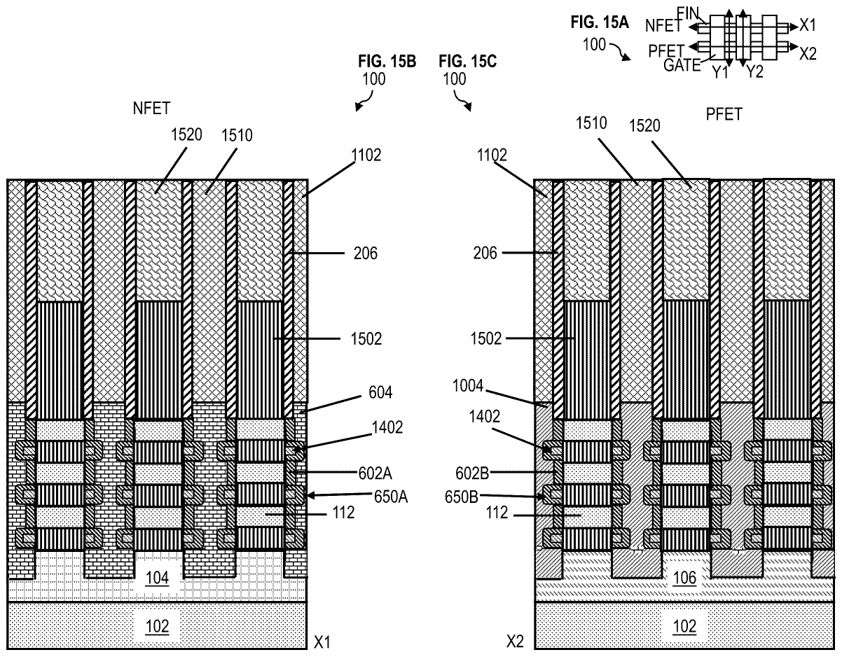

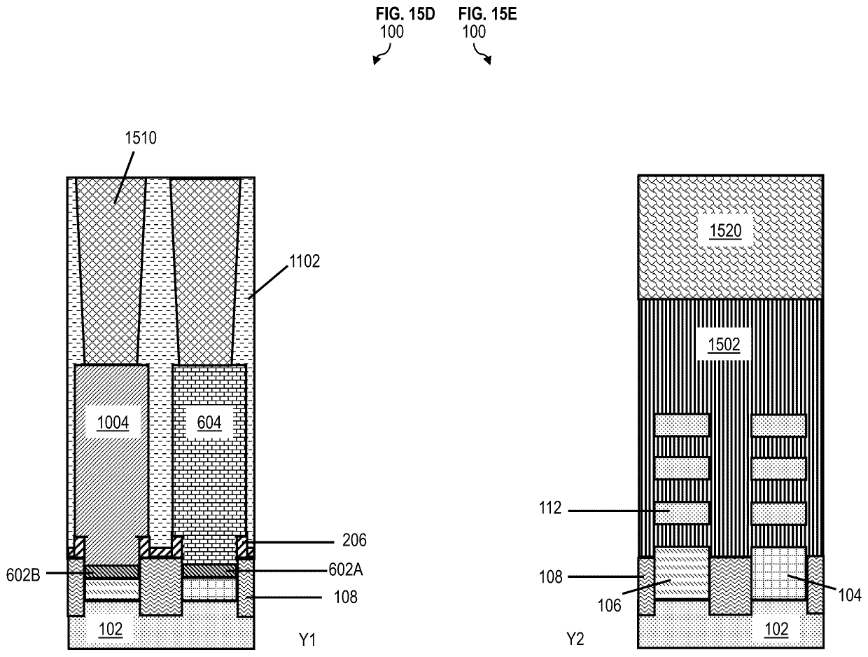

FIGS. 15A, 15B, 15C, 15D, and 15E depict the IC 100 after replacement metal gate processing and metal contact formation. A gate structure 1502 is formed, and a self-aligned contact (SAC) cap 1520 is formed on the gate structure 1502. The gate structure 1502 may include an inter-layer (IL), high-k dielectric material on the interfacial liner, work function materials around the high-k dielectric material, and a gate metal fill. The SAC cap 1520 may include dielectric materials. Etching is performed to form trenches, and metal is deposited in the etched trenches to form source/drain contacts 1510.

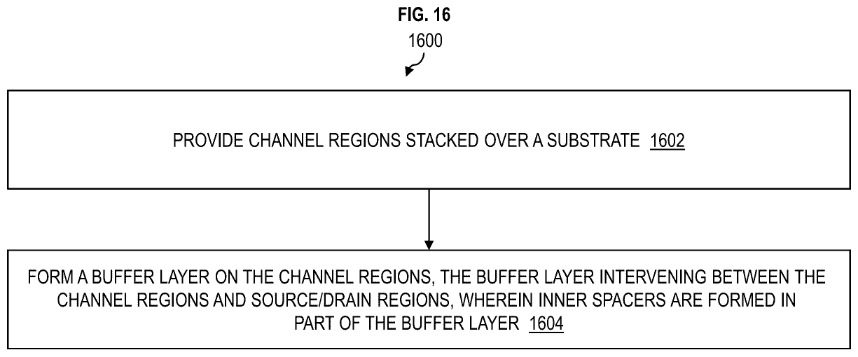

FIG. 16 is a flowchart of a method 1600 for forming an IC 100 having (late) inner spacers with stress engineering by source/drain epitaxial material for nanosheets according to one or more embodiments. Reference can be made to any figures discussed herein.

At block 1602, the method 1600 includes providing channel regions (e.g., semiconductor layers 112) stacked over a substrate 102. At block 1604, the method 1600 includes forming a buffer layer 602 on the channel regions (e.g., semiconductor layers 112), the buffer layer intervening between the channel regions (e.g., semiconductor layers 112) and source/drain regions (e.g., source/drain regions 604 and 1004), where inner spacers 1402 are formed in part of the buffer layer 602.

Additionally, a gate structure 1502 is between the channel regions (e.g., semiconductor layers 112) and is adjacent to the inner spacers, a thickness (e.g., T3) of the inner spacers 1402 in a dimension being less than a thickness (e.g., T2) of the gate structure 1502. A thickness (e.g., T3) of the inner spacers in a dimension is less than a spacing between the channel regions.

The buffer layer 602 is a continuous piece of material on sides of the channel regions (e.g., semiconductor layers 112). The buffer layer 602 comprises undoped silicon. The source/drain regions (e.g., source/drain regions 604 and 1004) comprise epitaxially grown material having a crystalline orientation matching the buffer layer 602. The inner spacers 1402 comprise a dielectric material. The buffer layer 602 comprises an extension (e.g., bump portions 650A and 650B) that protrudes in a first dimension, the extension having a gap 1202; and the inner spacers 1402 are formed in the gap 1202 of the extension.

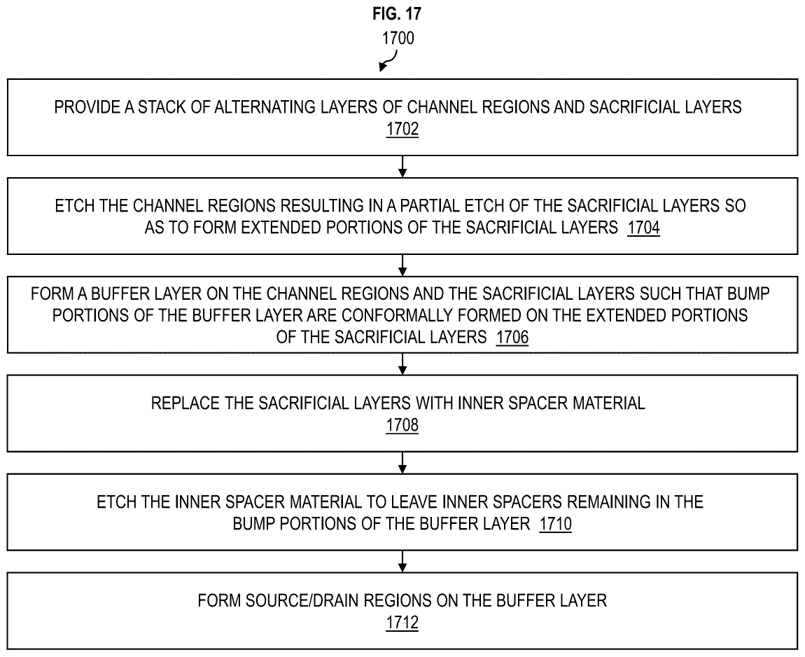

FIG. 17 is a flowchart of a method 1700 for forming an IC 100 having (late) inner spacers with stress engineering by source/drain epitaxial material for nanosheets according to one or more embodiments. Reference can be made to any figures discussed herein.

At block 1702, the method 1700 includes providing a stack (e.g., nanosheet stack 150) of alternating layers of channel regions (e.g., semiconductor layers 112) and sacrificial layers 110. At block 1704, the method 1700 includes etching the channel regions resulting in a partial etch of the sacrificial layers 110 so as to form extended portions (e.g., extensions 502A and 502B) of the sacrificial layers 110. At block 1706, the method 1700 includes forming a buffer layer 602 on the channel regions (e.g., semiconductor layers 112) and the sacrificial layers 110 such that bump portions (e.g., bump portions 650A and 650B) of the buffer layer 602 are conformally formed on the extended portions (e.g., extensions 502A and 502B) of the sacrificial layers 110. At blocks 1708 and 1710, the method 1700 includes replacing the sacrificial layers 110 with inner spacer material (e.g., dielectric material 1302) and etching the inner spacer material to leave inner spacers 1402 remaining in the bump portions (e.g., bump portions 650A and 650B) of the buffer layer 602. At block 1712, the method 1700 includes forming source/drain regions (e.g., source/drain regions 604 and 1004) on the buffer layer 602.

As discussed herein, gate material is formed around the semiconductor layers. The gate material includes high-k material and work function material generally referred to as a high-k metal gate (HKMG). Techniques for forming HKMG in gate openings are well-known in the art and, thus, the details have been omitted in order to allow the reader to focus on the salient aspects of the disclosed methods. However, it should be understood that such HKMG will generally include formation of one or more gate dielectric layers (e.g., an inter-layer (IL) oxide and a high-k gate dielectric layer), which are deposited so as to line the gate openings, and formation of one or more metal layers, which are deposited onto the gate dielectric layer(s) so as to fill the gate openings. The materials and thicknesses of the dielectric and metal layers used for the HKMG can be preselected to achieve desired work functions given the conductivity type of the FET. To avoid clutter in the drawings and to allow the reader to focus on the salient aspects of the disclosed methods, the different layers within the HKMG stack are not illustrated. For explanation purposes, a high-k gate dielectric layer can be, for example, a dielectric material with a dielectric constant that is greater than the dielectric constant of silicon dioxide (i.e., greater than 3.9). Exemplary high-k dielectric materials include, but are not limited to, hafnium (Hf)-based dielectrics (e.g., hafnium oxide, hafnium silicon oxide, hafnium silicon oxynitride, hafnium aluminum oxide, etc.) or other suitable high-k dielectrics (e.g., aluminum oxide, tantalum oxide, zirconium oxide, etc.). Optionally, the metal layer(s) can include a work function metal that is immediately adjacent to the gate dielectric layer and that is preselected in order to achieve an optimal gate conductor work function given the conductivity type of the nanosheet-FET. For example, the optimal gate conductor work function for the PFETs can be, for example, between about 4.9 eV and about 5.2 eV. Exemplary metals (and metal alloys) having a work function within or close to this range include, but are not limited to, ruthenium, palladium, platinum, cobalt, and nickel, as well as metal oxides (aluminum carbon oxide, aluminum titanium carbon oxide, etc.) and metal nitrides (e.g., titanium nitride, titanium silicon nitride, tantalum silicon nitride, titanium aluminum nitride, tantalum aluminum nitride, etc.). The optimal gate conductor work function for NFETs can be, for example, between 3.9 eV and about 4.2 eV. Exemplary metals (and metal alloys) having a work function within or close to this range include, but are not limited to, hafnium, zirconium, titanium, tantalum, aluminum, and alloys thereof, such as, hafnium carbide, zirconium carbide, titanium carbide, tantalum carbide, and aluminum carbide. The metal layer(s) can further include a fill metal or fill metal alloy, such as tungsten, a tungsten alloy (e.g., tungsten silicide or titanium tungsten), cobalt, aluminum, or any other suitable fill metal or fill metal.

Although not shown, contact formation and ILD formation are performed. ILD material can be deposited, source/drain contact openings are patterned by conventional lithography, and then metal is deposited to fill the cavities thereby forming metal contacts. A portion of the metal contacts may include silicide, resulting from the interface of the metal material and semiconductor material. The metal contacts are source/drain contacts that are respectively connected to epitaxial source/drain regions.

The ILD material can be SiO₂, SiN, a low-k dielectric material or an ultra-low-k dielectric material. Low-k dielectric materials may generally include dielectric materials having a k value of about 3.9 or less. The ultra-low-k dielectric material generally includes dielectric materials having a k value less than 2.5. Unless otherwise noted, all k values mentioned in the present application are measured relative to a vacuum. Exemplary ultra-low-k dielectric materials generally include porous materials such as porous organic silicate glasses, porous polyamide nanofoams, silica xerogels, porous hydrogen silsequioxane (HSQ), porous methylsilsesquioxane (MSQ), porous inorganic materials, porous CVD materials, porous organic materials, or combinations thereof. The ultra-low-k dielectric material can be produced using a templated process or a sol-gel process as is generally known in the art. In the templated process, the precursor typically contains a composite of thermally labile and stable materials. After film deposition, the thermally labile materials can be removed by thermal heating, leaving pores in the dielectric film. In the sol gel process, the porous low-k dielectric films can be formed by hydrolysis and polycondensation of an alkoxide(s) such as tetraetehoxysilane (TEOS).

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The phrase “selective to,” such as, for example, “a first element selective to a second element,” means that the first element can be etched and the second element can act as an etch stop.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

As noted above, atomic layer etching processes can be used in the present invention for via residue removal, such as can be caused by via misalignment. The atomic layer etch process provide precise etching of metals using a plasma-based approach or an electrochemical approach. The atomic layer etching processes are generally defined by two well-defined, sequential, self-limiting reaction steps that can be independently controlled. The process generally includes passivation followed selective removal of the passivation layer and can be used to remove thin metal layers on the order of nanometers. An exemplary plasma-based approach generally includes a two-step process that generally includes exposing a metal such a copper to chlorine and hydrogen plasmas at low temperature (below 20° C.). This process generates a volatile etch product that minimizes surface contamination. In another example, cyclic exposure to an oxidant and hexafluoroacetylacetone (Hhfac) at an elevated temperature such as at 275° C. can be used to selectively etch a metal such as copper. An exemplary electrochemical approach also can include two steps. A first step includes surface-limited sulfidization of the metal such as copper to form a metal sulfide, e.g., Cu₂S, followed by selective wet etching of the metal sulfide, e.g., etching of Cu₂S in HCl. Atomic layer etching is relatively recent technology and optimization for a specific metal is well within the skill of those in the art. The reactions at the surface provide high selectivity and minimal or no attack of exposed dielectric surfaces.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The photoresist can be formed using conventional deposition techniques such chemical vapor deposition, plasma vapor deposition, sputtering, dip coating, spin-on coating, brushing, spraying and other like deposition techniques can be employed. Following formation of the photoresist, the photoresist is exposed to a desired pattern of radiation such as X-ray radiation, extreme ultraviolet (EUV) radiation, electron beam radiation or the like. Next, the exposed photoresist is developed utilizing a conventional resist development process.

After the development step, the etching step can be performed to transfer the pattern from the patterned photoresist into the interlayer dielectric. The etching step used in forming the at least one opening can include a dry etching process (including, for example, reactive ion etching, ion beam etching, plasma etching or laser ablation), a wet chemical etching process or any combination thereof.

For the sake of brevity, conventional techniques related to making and using aspects of the invention may or may not be described in detail herein. In particular, various aspects of computing systems and specific computer programs to implement the various technical features described herein are well known. Accordingly, in the interest of brevity, many conventional implementation details are only mentioned briefly herein or are omitted entirely without providing the well-known system and/or process details.

In some embodiments, various functions or acts can take place at a given location and/or in connection with the operation of one or more apparatuses or systems. In some embodiments, a portion of a given function or act can be performed at a first device or location, and the remainder of the function or act can be performed at one or more additional devices or locations.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

The corresponding structures, materials, acts, and equivalents of all means or step plus function elements in the claims below are intended to include any structure, material, or act for performing the function in combination with other claimed elements as specifically claimed. The present disclosure has been presented for purposes of illustration and description but is not intended to be exhaustive or limited to the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

The diagrams depicted herein are illustrative. There can be many variations to the diagram or the steps (or operations) described therein without departing from the spirit of the disclosure. For instance, the actions can be performed in a differing order or actions can be added, deleted or modified. Also, the term “coupled” describes having a signal path between two elements and does not imply a direct connection between the elements with no intervening elements/connections therebetween. All of these variations are considered a part of the present disclosure.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include both an indirect “connection” and a direct “connection.”

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor structure comprising:
channel regions stacked over a substrate and connected to source/drain regions;
a buffer layer intervening between the channel regions and the source/drain regions; and
inner spacers formed in part of the buffer layer.

2. The semiconductor structure of claim 1, wherein a gate structure is between the channel regions and is adjacent to the inner spacers, a thickness of the inner spacers in a dimension being less than a thickness of the gate structure.

3. The semiconductor structure of claim 1, wherein a thickness of the inner spacers in a dimension is less than a spacing between the channel regions.

4. The semiconductor structure of claim 1, wherein the buffer layer is a continuous piece of material on sides of the channel regions.

5. The semiconductor structure of claim 1, wherein the buffer layer comprises undoped silicon.

6. The semiconductor structure of claim 1, wherein the source/drain regions comprise epitaxially grown material having a crystalline orientation matching the buffer layer.

7. The semiconductor structure of claim 1, wherein the inner spacers comprise a dielectric material.

8. The semiconductor structure of claim 1, wherein:
the buffer layer comprises an extension that protrudes in a first dimension, the extension having a gap; and
the inner spacers are formed in the gap of the extension.

9. A method comprising:
providing channel regions stacked over a substrate; and
forming a buffer layer on the channel regions, the buffer layer intervening between the channel regions and source/drain regions, wherein inner spacers are formed in part of the buffer layer.

10. The method of claim 9, wherein a gate structure is between the channel regions and is adjacent to the inner spacers, a thickness of the inner spacers in a dimension being less than a thickness of the gate structure.

11. The method of claim 9, wherein a thickness of the inner spacers in a dimension is less than a spacing between the channel regions.

12. The method of claim 9, wherein the buffer layer is a continuous piece of material on sides of the channel regions.

13. The method of claim 9, wherein the buffer layer comprises undoped silicon.

14. The method of claim 9, wherein the source/drain regions comprise epitaxially grown material having a crystalline orientation matching the buffer layer.

15. The method of claim 9, wherein the inner spacers comprise a dielectric material.

16. The method of claim 9, wherein:
the buffer layer comprises an extension that protrudes in a first dimension, the extension having a gap; and
the inner spacers are formed in the gap of the extension.

17. A method comprising:
providing a stack of alternating layers of channel regions and sacrificial layers;
etching the channel regions resulting in a partial etch of the sacrificial layers so as to form extended portions of the sacrificial layers;
forming a buffer layer on the channel regions and the sacrificial layers such that bump portions of the buffer layer are conformally formed on the extended portions of the sacrificial layers;
replacing the sacrificial layers with inner spacer material;
etching the inner spacer material to leave inner spacers remaining in the bump portions of the buffer layer; and
forming source/drain regions on the buffer layer.

18. The method of claim 17, wherein a gate structure is between the channel regions and is adjacent to the inner spacers, a thickness of the inner spacers in a dimension being less than a thickness of the gate structure.

19. The method of claim 17, wherein a thickness of the inner spacers in a dimension is less than a spacing between the channel regions.

20. The method of claim 17, wherein the buffer layer is a continuous piece of material on sides of the channel regions.

21. The method of claim 17, wherein the buffer layer comprises undoped silicon.

22. The method of claim 17, wherein the source/drain regions comprise epitaxially grown material having a crystalline orientation matching the buffer layer.

23. The method of claim 17, wherein the inner spacer material comprises a dielectric material.

24. A semiconductor structure comprising:
channel regions vertically stacked over a substrate and connected to source/drain regions;
a buffer layer intervening between the channel regions and the source/drain regions, the buffer layer comprising bump portions that extend laterally; and
inner spacers formed in the bump portions of the buffer layer.

25. The semiconductor structure of claim 24, wherein a gate structure is between the channel regions and is adjacent to the inner spacers, a thickness of the inner spacers in a dimension being less than a thickness of the gate structure.
